(19) United States
(12) Patent Application Publication
(10) Pub. No.: US 2009/0146255 A1
(43) Pub. Date: Jun. 11, 2009

(54) Capacitor for Semiconductor Device and Method for Manufacturing the Same

(76) Inventor: Sung Su KIM, Jeonju-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/239,932

(22) Filed: Sep. 29, 2008

(30) Foreign Application Priority Data
Dec. 10, 2007 (KR) 10-2007-0127492

(51) Int. Cl. H01L 29/00; H01L 21/20

(52) U.S. Cl. 257/532; 438/396; 257/E29.001; 257/E21.09

(57) ABSTRACT

Disclosed is a capacitor of a semiconductor device, capable of varying a capacitance according to a design of the semiconductor device. The capacitor can include a first electrode area and a second electrode area with a dielectric therebetween. The first electrode area can have a metal electrode spanning the entire first electrode area. The second electrode area can include a plurality of metal electrodes connected to each other through thin bridge patterns. Internal pads can be arranged around the electrode areas and are connected to certain ones of the plurality of metal electrodes of the second electrode area in order to provide a voltage capable of melting or breaking certain ones of the thin bridge patterns. The capacitance of the capacitor arranged according to embodiments can be adjusted to a desirable level using the internal pads. Therefore, a designer can easily design the capacitor or change the design of the capacitor.

### CROSS-REFERENCE TO RELATED APPLICATION

The present application claims the benefit under 35 U.S.C. §119 of Korean Patent Application No. 10-2007-0127492, filed on Dec. 10, 2007, which is hereby incorporated by reference in its entirety.

### BACKGROUND

Recently, as semiconductor devices have become highly integrated, a semiconductor device, in which an analogue capacitor is integrated together with a logic circuit, has been studied and developed as a product. The analogue capacitor generally used in the logic circuit has a PIP (Polysilicon/Insulator/Polysilicon) structure or a MIM (Metal/Insulator/Metal) structure.

In contrast to a MOS (Metal Oxide Semiconductor) capacitor or a junction capacitor, the PIP analogue capacitor and the MIM analogue capacitor are independent from bias. Therefore, the PIP analogue capacitor and the MIM analogue capacitor are widely used for analogue products requiring high precision.

A bottom electrode and a top electrode of the MIM capacitor can be fabricated when a metal interconnection is formed.

Among the semiconductor devices formed on a semiconductor substrate through a series of processes, the MIM capacitor has a stack structure, in which an insulator layer having dielectric characteristics is formed on a metal of a bottom electrode and a metal of a top electrode is formed on the insulator layer. Since a capacitance of such an MIM capacitor is set by the area of the smaller of the two electrodes making up the MIM capacitor, a trimming of the circuit design is very difficult even when the trimming of the circuit design is required. In order to solve the above problem and ensure a simulation margin in the circuit design, a variable MIM capacitor is necessary.

### BRIEF SUMMARY

Embodiments of the present invention provide a capacitor of a semiconductor device and a method for manufacturing the same, capable of varying a capacitance according to a design of the semiconductor device.

A capacitor of a semiconductor device according to an embodiment includes a bottom electrode on a substrate; a dielectric layer on the bottom electrode; a plurality of top electrodes on the dielectric layer above the bottom electrode; bridge patterns for connecting adjacent top electrodes of the plurality of top electrodes to each other; and pads connected to the plurality of top electrodes.

A method for manufacturing a capacitor of a semiconductor device according to an embodiment includes forming a bottom electrode on a substrate; forming a dielectric layer to cover the bottom electrode; forming a metal layer on the dielectric layer; and patterning the metal layer to form a plurality of top electrodes overlapping the bottom electrode, bridge patterns for connecting adjacent top electrodes to each other, and pads connected to the top electrodes.

A capacitor of a semiconductor device according to an embodiment includes a first electrode on a substrate; a dielectric layer on the first electrode; a second electrode on the dielectric layer; at least one auxiliary electrode disposed at a periphery of the second electrode; a bridge pattern for connecting the auxiliary electrode to the second electrode; and a pad connected to the auxiliary electrode.

A method for manufacturing a capacitor of a semiconductor device according to an embodiment includes forming a first electrode on a substrate; forming a dielectric layer covering the first electrode; forming a metal layer on the dielectric layer; and patterning the metal layer to form a second electrode overlapping the first electrode, at least one auxiliary electrode disposed at a periphery of the second electrode, a bridge pattern for connecting the auxiliary electrode to the second electrode, and pads connected to each of the at least one auxiliary electrode.

According to embodiments, the capacitance of a capacitor of the semiconductor device arranged according to an embodiment of the present invention can be adjusted to achieve a desirable capacitance level. Therefore, a designer can easily design the capacitor or change the design of the capacitor.

According to an embodiment, the capacitance of the device can be changed by using an internal pad connected to the capacitor without using external equipment, so that the capacitance is easily changed and a change of design is simplified.

### BRIEF DESCRIPTION OF THE DRAWINGS

FIG. 1 is a plan view of a capacitor of a semiconductor device according to a first embodiment.

FIG. 2 is a sectional view taken along line I-I′ of FIG. 1 according to an embodiment of the present invention.

FIGS. 3 to 5 are plan views showing a method for varying a capacitance of the capacitor of the semiconductor device arranged according to the first embodiment.

FIG. 6 is a plan view of a capacitor of a semiconductor device according to a second embodiment.

FIG. 7 is a plan view showing a method for varying a capacitance of the capacitor arranged according to the embodiment shown in FIG. 6.

FIG. 8 is a plan view of a capacitor of a semiconductor device according to a third embodiment.

FIGS. 9 to 12 are plan views showing a method for varying a capacitance of the capacitor of the semiconductor device arranged according to the third embodiment.

### DETAILED DESCRIPTION

A capacitor of a semiconductor device and a method for manufacturing the same according to embodiments of the present invention will be described in detail with reference to accompanying drawings. Although the preferred embodiments of the present invention have been disclosed for illustrative purposes, those skilled in the art will appreciate that various modifications, additions, deletions and substitutions are possible without departing from the scope and spirit of the invention as disclosed in the accompanying claims.

The terms “first” and “second” are used to distinguish members from each other, not to define the members. Accordingly, if the terms “first” and “second” are mentioned, plural members are provided, and the members may be selectively or alternatively used.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

In addition, it will also be understood that when the terms like “first” and “second” are used to describe members, the members are not limited by these terms. For example, a plurality of members may be provided. Therefore, when the terms like “first” and “second” are used, it will be apparent that the plurality of such members may be provided. In addition, the terms “first” and “second” can be selectively or exchangeably used for the members. In the figures, a dimension of each of elements is exaggerated for clarity of illustration, and the dimension of each of the elements may be different from an actual dimension of each of the elements. Not all elements illustrated in the drawings must be included and limited to the present disclosure, but the elements except essential features of the present disclosure may be added or deleted.

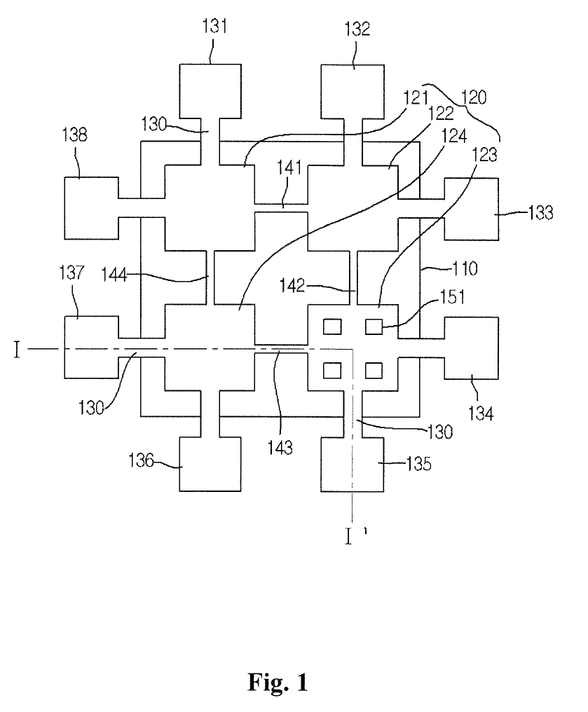

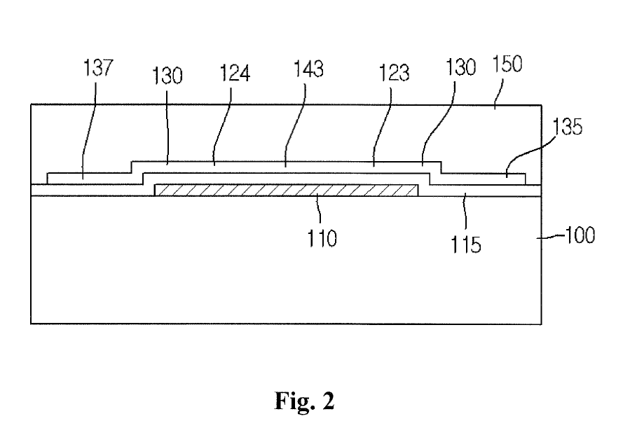

FIG. 1 is a plan view of a capacitor of a semiconductor device according to a first embodiment, and FIG. 2 is a sectional view taken along line I-I′ of FIG. 1.

Referring to FIGS. 1 and 2, a capacitor of a semiconductor device according to an embodiment can include a bottom electrode 110, a top electrode 120 formed on the bottom electrode 110, and a dielectric layer 115 formed between the top electrode 120 and the bottom electrode 110.

An interlayer dielectric layer 150 can be formed on a semiconductor substrate 100 having the capacitor, and a via-pattern 151 can be formed in the interlayer dielectric layer 150 for applying an electric signal to the top electrode 120.

In certain embodiments, the dielectric layer 115 can include high-K insulating material.

The bottom electrode 110 can include at least one material selected from the group consisting of Ti, TiN, Ta, TaN, Cu, Al, Pt, Ru, Ir, Rh, Os and an alloy thereof. The bottom electrode 110 can be formed in a single layer structure or a multi-layer structure.

The top electrode 120 can also include at least one material selected from the group consisting of Ti, TiN, Ta, TaN, Cu, Al, Pt, Ru, Ir, Rh, Os and an alloy thereof. In addition, the top electrode 120 can have a single layer structure or a multi-layer structure.

The top electrode 120 disposed on the bottom electrode 110 has a structure of at least two electrodes connected to each other. The at least two electrodes can have, for example, a polygonal shape.

For example, as shown in FIG. 1, the top electrode 120 can include four top electrodes: a first top electrode 121, a second top electrode 122, a third top electrode 123, and a fourth top electrode 124.

The first to fourth top electrodes 121, 122, 123 and 124 can be electrically connected to each other using bridge patterns. The via-pattern 151 can be formed on at least one of the top electrodes (e.g., one of the first to fourth top electrodes 121, 122, 123 and 124). In the embodiment illustrated in FIG. 1, the via-pattern 151 is formed on the third top electrode 123). The remaining top electrodes, which are not directly connected to the via-pattern 151, can be electrically connected to the via-pattern 151 through the bridge patterns electrically connecting the first to fourth top electrodes 121, 122, 123, and 124 to each other.

The bridge patterns can be formed to have a minimum width allowable in a process of manufacturing the semiconductor device such that the bridge patterns may be disconnected or broken when high current is applied to the bridge patterns.

In one embodiment, the bridge patterns can include a first bridge pattern 141 connecting the first top electrode 121 to the second top electrode 122, a second bridge pattern 142 connecting the second top electrode 122 to the third top electrode 123, a third bridge pattern 143 connecting the third top electrode 123 to the fourth top electrode 124, and a fourth bridge pattern 144 connecting the fourth top electrode 124 to the first top electrode 121.

The first to fourth top electrodes 121, 122, 123 and 124 and the first to fourth bridge patterns 141, 142, 143 and 144 are disposed corresponding to an upper part of the bottom electrode 110. That is, the top electrodes (121, 122, 123 and 124) that make up the top electrode 120 and the bridge patterns (141, 142, 143 and 144) are provided directly above the bottom electrode 110.

One or more pads can be formed to be electrically connected to the top electrodes. A connecting wire 130 can be formed to provide the electrical connections between the electrodes of the top electrode 120 and the pads. In one embodiment, two pads can be connected to each top electrode of the top electrode 120. For example, a first pad 131 and an eighth pad 138 can be electrically connected to the first top electrode 121 through connecting wires 130, a second pad 132 and a third pad 133 can be electrically connected to the second top electrode 122 through connecting wires 130, a fourth pad 134 and a fifth pad 135 can be electrically connected to the third top electrode 123 through connecting wires 130, and a sixth pad 136 and a seventh pad 137 can be electrically connected to the fourth top electrode 124 through connecting wires 130.

According to an embodiment, the first to fourth top electrodes 121, 122, 123 and 124, the pads 131, 132, 133, 134, 135, 136, 137 and 138, the first to fourth bridge patterns 141, 142,143 and 144, and the connecting wire 130 can be integrally formed with each other in the form of a single pattern.

The pads of the top electrode 120 are formed on a region in which the pads do not overlap with the bottom electrode 110. Accordingly, as shown in FIG. 1, the first to eighth pads 131, 132, 133, 134, 135, 136, 137 and 138 can be provided in a region surrounding the bottom electrode 110.

The first to fourth top electrodes 121, 122, 123 and 124, the first to fourth bridge patterns 141, 142, 143 and 144 and the first to eighth pads 131, 132, 133, 134, 135, 136, 137 and 138 can be formed on the same layer by patterning a metal layer for forming the top electrode 120.

According to embodiments of the present invention, a variable capacitor capable of adjusting the capacitance thereof can be obtained by selecting at least one of the top electrodes of the top electrode 120 (e.g., at least one of the first to fourth top electrodes 121, 122, 123 and 124) and then electrically isolating the selected top electrode from the remaining top electrodes.

The selected top electrode can be isolated by breaking the bridge patterns connected to the selected top electrode.

Since the bridge patterns (e.g. first to fourth bridge patterns 141, 142, 143 and 144) have a minimum design rule allowable in the semiconductor process, if high current is applied to one or more of the bridge patterns 141, 142, 143 and 144 through one or more of the pads 131, 132, 133, 134, 135, 136, 137 and 138, the bridge patterns 141, 142, 143 and 144 can become disconnected.

For example, in a process of manufacturing a 0.13-micron CMOS (Complimentary Metal Oxide Semiconductor) device, the bridge pattern can have a design rule of about 0.3 μm or smaller, for example, to about 0.001 μm.

In addition, a range of high current varies depending on the metal forming the bridge pattern. For example, the high current can have a range of about 0.5 A to about 8 A.

By electrically isolating some of the top electrodes of the top electrode 120 from the remaining top electrodes, the capacitance of the capacitor can be changed as described below, and a variable capacitor can be obtained based on the above characteristics.

The capacitance of a capacitor can be obtained by using the following equation.

$$C = ɛ \frac{S}{d} [ F ]$$

In the above equation, C is a capacitance (unit: F), E is a dielectric constant, S is an area of the electrode, and d is a distance between electrodes.

Since the dielectric constant ∈ and the distance of the electrodes d are fixed, the capacitance can be adjusted by changing the area of the electrode S.

For example, the capacitance of a capacitor arranged according to an embodiment of the present invention can be adjusted by electrically disconnecting the first top electrode 121 from the second top electrode 122, the third top electrode 123, and the fourth top electrode 124. This can be accomplished by causing a disconnection of the first bridge pattern 141 and the fourth bridge pattern 144.

In this example, if the first to fourth top electrodes 121, 122, 123 and 124 have the same area, the capacitance C of the capacitor is reduced by ¼C, so that the capacitor has a capacitance of ¾C.

In certain embodiments, the first to fourth top electrodes 121, 122, 123 and 124 can have a size different from each other. Therefore, the capacitance can be varied accordingly.

Hereinafter, a method of selectively disconnecting the bridge patterns of the top electrode 120 will be described.

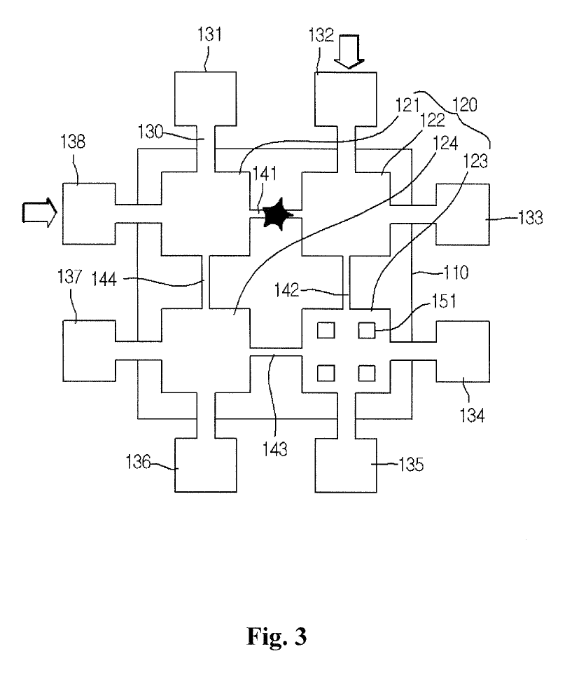

FIGS. 3 to 5 are plan views showing a method for varying the capacitance of the capacitor of a semiconductor device arranged according to the first embodiment.

Referring to FIG. 3, voltage can be applied to the second pad 132 and the eighth pad 138 such that high current is applied between the second pad 132 and the eighth pad 138.

The current can flow in the sequence of the eighth pad 138, the connecting wire, the first top electrode 121, the first bridge pattern 141, the second top electrode 122, the connecting wire 130, and the second pad 132.

At this time, the first bridge pattern 141, which has a width smaller than the width of the other patterns having the current applied through, is melted or broken so that the first bridge pattern 141 becomes disconnected.

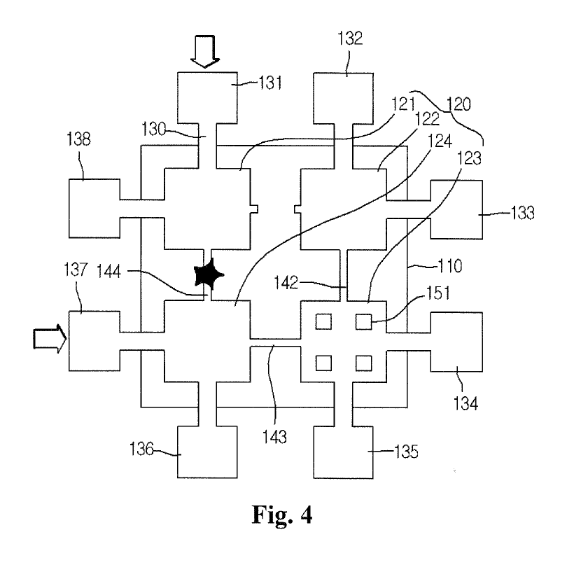

Referring to FIG. 4, after the first bridge pattern 141 is disconnected, voltage can be applied to the first pad 131 and the seventh pad 137 of the capacitor such that high current is applied between the first pad 131 and the seventh pad 137.

In this case, the fourth bridge pattern 144, which has a width smaller than the width of the other patterns having the current applied through, is melted or broken so that the fourth bridge pattern becomes disconnected.

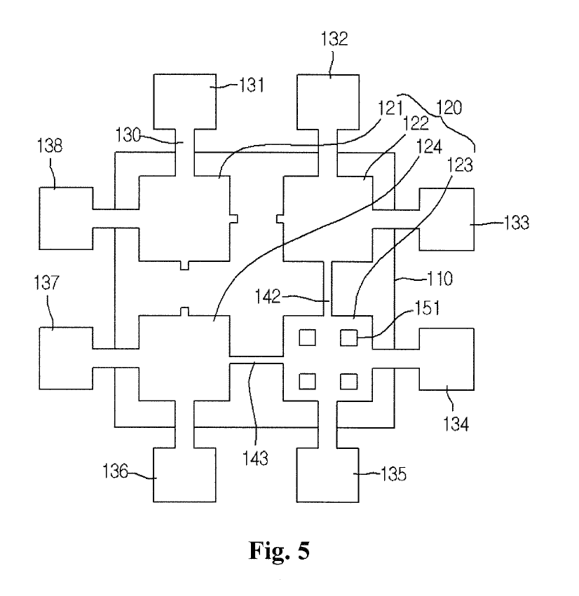

Accordingly, as shown in FIG. 5, the first and fourth bridge patterns 141 and 144 are disconnected so that the first top electrode 121 is electrically isolated from the second top electrode 122, the third top electrode 123, and the fourth top electrode 124. Accordingly, the effective area of the top electrode 120 is reduced, so that the capacitance of the capacitor may vary.

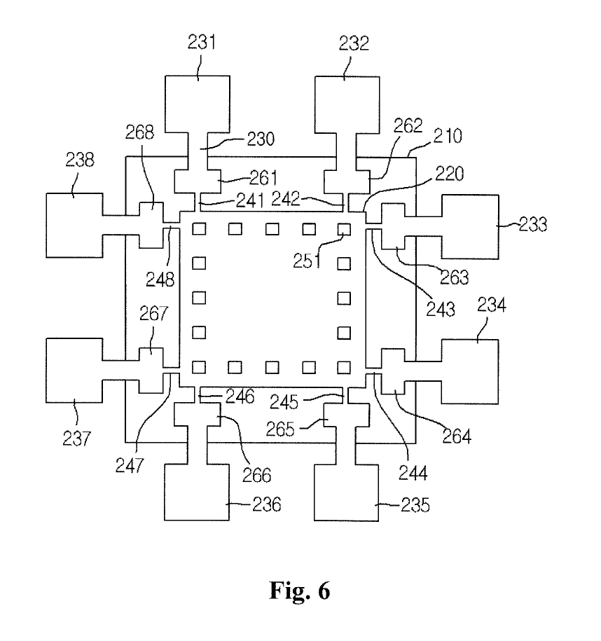

FIG. 6 is a plan view of a capacitor of a semiconductor device according to a second embodiment.

Referring to FIG. 6, the capacitor can include a bottom electrode 210, a top electrode 220 disposed on the bottom electrode 210, and one or more auxiliary electrodes disposed around a periphery of the top electrode 220 and also formed on the bottom electrode 210. A dielectric layer (not shown) is provided between the bottom electrode 210 and the top electrode 220 and the one or more auxiliary electrodes. The one or more auxiliary electrodes can be electrically connected to the top electrode 220 through bridge patterns.

As shown in FIG. 6, the one or more auxiliary electrodes can include a first auxiliary electrode 261, a second auxiliary electrode 262, a third auxiliary electrode 263, a fourth auxiliary electrode 264, a fifth auxiliary electrode 265, a sixth auxiliary electrode 266, a seventh auxiliary electrode 267, and an eighth auxiliary electrode 268 disposed about the periphery of the top electrode 220.

In addition, according to an embodiment, the first auxiliary electrode 261 can be connected to the top electrode 220 through a first bridge pattern 241, the second auxiliary electrode 262 can be connected to the top electrode 220 through a second bridge pattern 242, the third auxiliary electrode 263 can be connected to the top electrode 220 through a third bridge pattern 243, the fourth auxiliary electrode 264 can be connected to the top electrode 220 through a fourth bridge pattern 244, the fifth auxiliary electrode 265 can be connected to the top electrode 220 through a fifth bridge pattern 245, the sixth auxiliary electrode 266 can be connected to the top electrode 220 through a sixth bridge pattern 246, the seventh auxiliary electrode 267 can be connected to the top electrode 220 through a seventh bridge pattern 241, and the eighth auxiliary electrode 268 can be connected to the top electrode 220 through an eighth bridge pattern 241. The bridge patterns (e.g., first to eighth bridge patterns 241, 242, 243, 244, 245, 246, 247 and 248) can be formed to have a minimum design rule allowable in the process of manufacturing the semiconductor device.

One or more pads can be formed to be electrically connected to the corresponding ones of the one or more auxiliary electrodes. A connecting wire 230 can be formed to provide electrical connection between the pads and the auxiliary electrodes. For example, a first pad 231 can be electrically connected to the first auxiliary electrode 261 through connecting wire 230, a second pad 232 can be electrically connected to the second auxiliary electrode 262 through connecting wire 230, a third pad 233 can be electrically connected to the third auxiliary electrode 263 through connecting wire 230, a fourth pad 234 can be electrically connected to the fourth auxiliary electrode 264 through connecting wire 230, a fifth pad 235 can be electrically connected to the fifth auxiliary electrode 265 through connecting wire 230, a sixth pad 236 can be electrically connected to the sixth auxiliary electrode 266 through connecting wire 230, a seventh pad 237 can be electrically connected to the seventh auxiliary electrode 267 through connecting wire 230, and an eighth pad 238 can be electrically connected to the eighth auxiliary electrode 268 through connecting wire 230.

According to an embodiment, the first to eighth auxiliary electrodes 261, 262, 263, 264, 265, 266, 267 and 268, the first to eighth pads 231, 232, 233, 234, 235, 236, 237 and 238, first to eighth bridge patterns 241, 242, 243, 244, 245, 246, 247 and 248, and the connecting wire 230 can be integrally formed with each other in the form of a single pattern.

According to embodiments, voltage can be applied to the top electrode 220 through a via-pattern 251.

According to this embodiment, the capacitance of the capacitor can be finely adjusted by using the auxiliary electrodes 261, 262, 263, 264, 265, 266, 267 and 268.

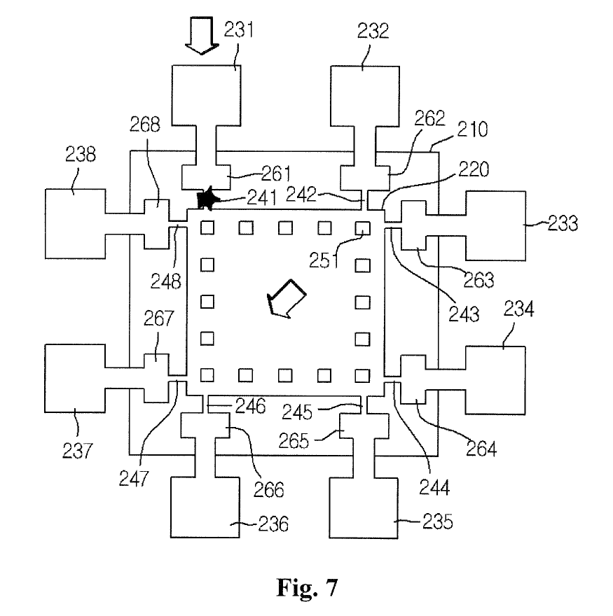

FIG. 7 is a plan view showing a method for varying the capacitance of the capacitor shown in FIG. 6. The capacitance can be varied by adjusting the number of auxiliary electrodes that remain connected to the top electrode 220. According to an embodiment, a selected auxiliary electrode can be disconnected from the top electrode by an application of voltage to the pad connected to the selected auxiliary electrode.

For example, referring to FIG. 7, voltage can be applied to the first pad 231 and the top electrode 220 such that high current is applied to the first bridge pattern 241, so that the first bridge pattern 241 is melted or broken due to overload applied thereto. Accordingly, the first bridge pattern 241 is disconnected.

Therefore, an area of the first auxiliary electrode 261 can be reduced, so that the total capacitance of the capacitor may vary.

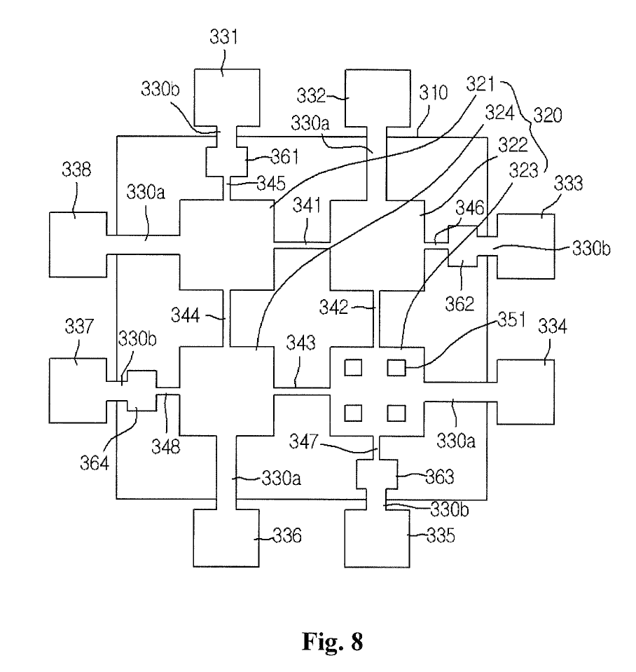

FIG. 8 is a plan view of a capacitor of a semiconductor device according to a third embodiment.

Referring to FIG. 8, a capacitor according to the third embodiment can include a bottom electrode 310, a top electrode 320 having a plurality of top electrodes connected to each other through bridge patterns, at least one auxiliary electrode connected to the top electrode 320 through a bridge pattern, and pads connected to the top electrode 320 and the at least one auxiliary electrode through connecting wire. A dielectric (not shown) is disposed between the bottom electrode 320 and the top patterns including the top electrode 320, the at least one auxiliary electrode, the bridge patterns, and the connecting wires.

In one embodiment, the top electrode 320 can include a first top electrode 321, a second top electrode 322, a third top electrode 323, and a fourth top electrode 324 disposed on the bottom electrode 310. A first bridge pattern 341 can connect the first top electrode 321 to the second top electrode 322, a second bridge pattern 342 can connect the second top electrode 322 to the third top electrode 323, a third bridge pattern 343 can connect the third top electrode 323 to the fourth top electrode 324, and a fourth bridge pattern 344 can connect the fourth top electrode 324 to the first top electrode 321.

In an embodiment, the at least one auxiliary electrode can include a first auxiliary electrode 361 connected to the first top electrode 321 through a fifth bridge pattern 345, a second auxiliary electrode 362 connected to the second top electrode 322 through a sixth bridge pattern 346, a third auxiliary electrode 363 connected to the third top electrode 323 through a seventh bridge pattern 347, and a fourth auxiliary electrode 364 connected to the fourth top electrode 324 through an eighth bridge pattern 348.

As shown in FIG. 8, the pads connected to the top electrodes and auxiliary electrodes through connecting wires can be arranged in a region around the periphery of the bottom electrode. In a specific embodiment, a first pad 331 can be connected to the first auxiliary electrode 361 through second connecting wire 330b, a second pad 332 can be connected to the second top electrode 322 through first connecting wire 330a, a third pad 333 can be connected to the second auxiliary electrode 362 through second connecting wire 330b, a fourth pad 334 can be connected to the third top electrode 323 through first connecting wire 330a, a fifth pad 335 can be connected to the third auxiliary electrode 363 through second connecting wire 330b, a sixth pad 336 can be connected to the fourth top electrode 324 through first connecting wire 330a, a seventh pad 337 can be connected to the fourth auxiliary electrode 364 through second connecting wire 330b, and an eighth pad 338 can be connected to the first top electrode 321 through first connecting wire 330a. The first to fourth top electrodes 321, 322, 323 and 324, the first to fourth auxiliary electrodes 361, 362, 363 and 364, the first to eighth pads 331, 332, 333, 334, 335, 336, 337 and 338, the first to eighth bridge patterns 341, 342,343, 344, 345, 346, 347 and 348, and the first and second connecting wires 130a and 130b can be integrally formed with each other in the form of a single pattern.

A via-pattern 351 can be formed on at least one of the first to fourth top electrodes 321, 322, 323 and 324. The remaining top electrodes, which are not directly connected to the via-pattern 351, can be electrically connected to the via-pattern 351 through the bridge patterns.

The bridge pattern has a minimum design rule allowable in the process for manufacturing the semiconductor device. Voltage can be applied to the top electrode 320 through the via-pattern 351.

As shown in FIG. 8, the first to eighth pads 331, 332, 333, 334, 335, 336, 337 and 338 are formed on a region where the pads 331, 332, 333, 334, 335, 336, 337 and 338 do not overlap with the bottom electrode 310.

According to an implementation of the third embodiment, the pads can be arranged similarly to that shown in FIG. 1, except an auxiliary electrode can be interposed between one of the two pads connected to a particular top electrode. For example, the first top electrode 321 is connected to one of the two pads while interposing one auxiliary electrode therebetween. In addition, the first top electrode 321 is directly connected to the remaining of the two pads through connecting wire.

One or more of the other top electrodes can also have such a structure. That is, the second and third top electrodes 322 and 323 can have a structure the same as that of the first top electrode 321. In a further embodiment, the fourth top electrode 324 can also have the structure the same as that of the first top electrode 321.

According to the third embodiment, in order to vary the capacitance of the capacitor, at least one of the first to fourth top electrodes 321, 322, 323 and 324 and at least one of the first to fourth auxiliary electrodes 361, 362, 363 and 364 are selected and isolated from the remaining top electrodes and auxiliary electrodes, so that the capacitance of the capacitor can be precisely adjusted to various values.

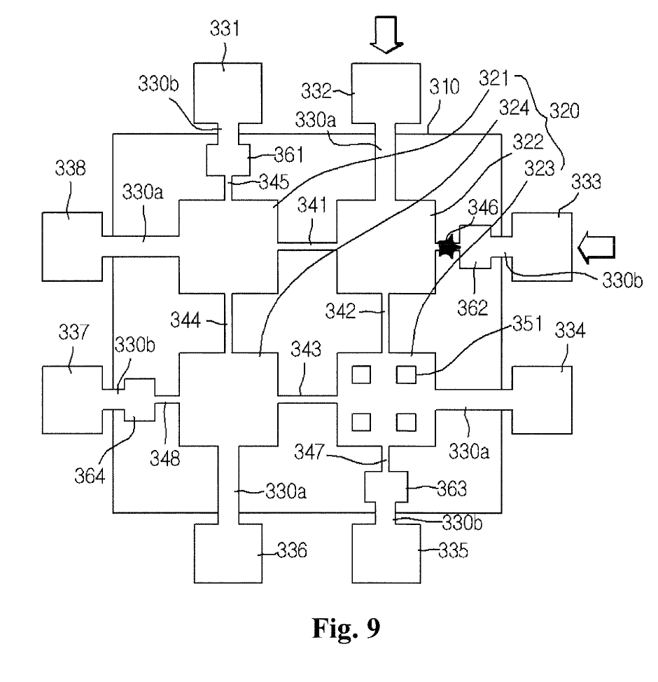

FIGS. 9 to 12 are plan views showing a method for varying the capacitance of the capacitor of the semiconductor device arranged according to a third embodiment.

As shown in FIG. 9, voltage can be applied to the second pad 332 and the third pad 333 such that high current is applied through the sixth bridge pattern 346 disposed between the second pad 332 and the third pad 333.

If the sixth bridge pattern 346 is broken by the high current, the area of the second auxiliary electrode 362 is excluded from the total area of the upper part of the capacitor, so that the capacitance of the capacitor is initially varied.

Thus, a capacitor having the initially varied capacitance may be used. Meanwhile, the capacitance of the capacitor can be secondarily adjusted such that the capacitor may have a capacitance different from the initially varied capacitance.

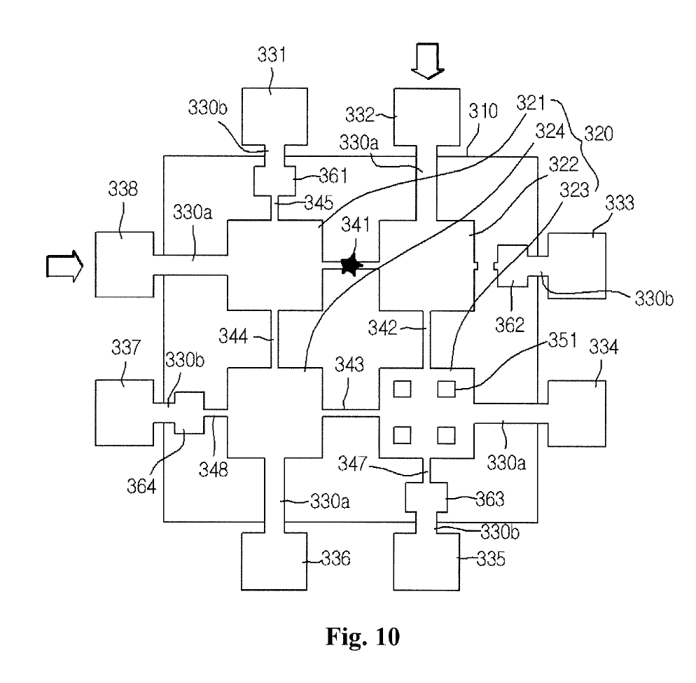

For example, referring to FIG. 10, voltage can be applied to the second pad 332 and the eighth pad 338 in the capacitor having the broken sixth bridge pattern 346.

As a result, high current is generated between the second pad 332 and the eighth pad 338, so that the first bridge pattern 341 is broken.

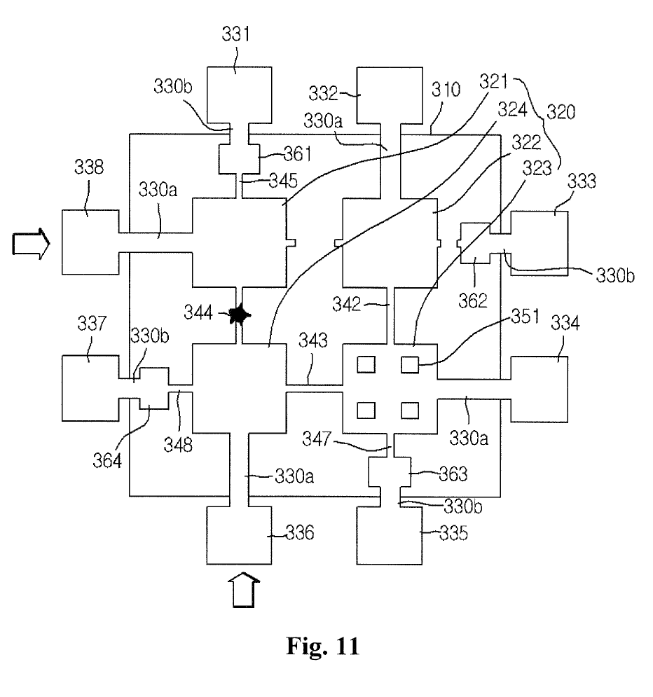

Then, the capacitor can be further adjusted. For example, as shown in FIG. 11, if voltage is applied to the sixth pad 336 and the eighth pad 338, high current is generated between the sixth pad 336 and the eighth pad 338, so that the fourth bridge pattern 344 can be broken.

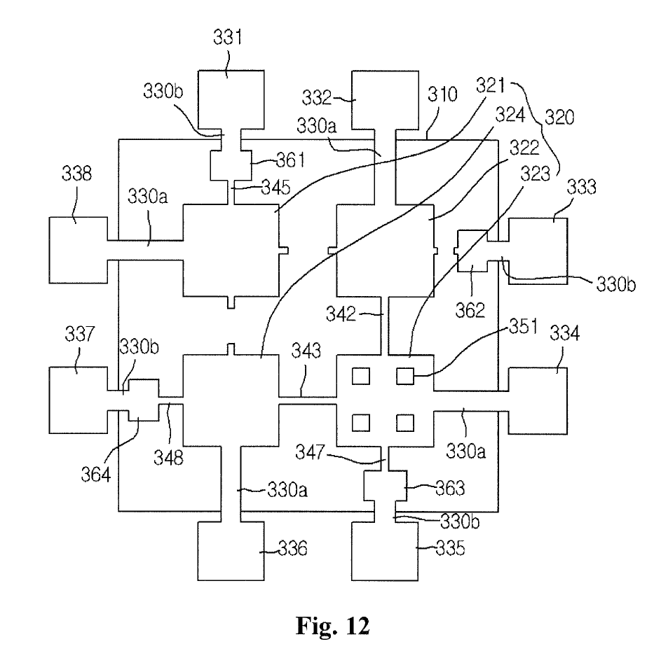

Accordingly, as shown in FIG. 12, the second auxiliary electrode 362, the first top electrode 321 and the first auxiliary electrode 361 are electrically isolated from the second top electrode 322, the third top electrode 323, and the fourth top electrode 324.

Accordingly, the effective area of the top electrode can be reduced, and the capacitance of the capacitor can be varied through use of internal pads.

Although the present embodiments have been described in that the area of the top electrode is adjusted to vary the capacitance of the capacitor, the present invention is not limited thereto. According to another embodiment, the capacitance can be adjusted by adopting the above structure of the top electrode in the bottom electrode.

According to an embodiment, the variable capacitor can be formed for a semiconductor device such that the area of the top electrode or the bottom electrode can be adjusted according to current used in the semiconductor device or an external power source, so that the capacitance of the capacitor can be easily varied.

In addition, since the capacitor according to the embodiments does not require external measurement equipment or additional apparatus for adjusting the capacitance, the manufacturing cost can be reduced and the product yield can be improved.

According to the capacitor of the present embodiments, the capacitance can be finely adjusted, so that a design modification can be ensured through fine tuning work. Further, the time required for modifying the design of a plurality of chips can be reduced through a trimming using semiconductor device inspection equipment.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A capacitor of a semiconductor device, comprising:
a first electrode;
a second electrode comprising a plurality of base electrodes, wherein adjacent base electrodes are connected to each other by bridge patterns;
a dielectric disposed between the first electrode and the second electrode, wherein the first electrode, the dielectric, and the second electrode are stacked on a semiconductor substrate; and
at least two pads connected to the second electrode, wherein the at least two pads are disposed at a region around the first electrode and the second electrode.

2. The capacitor of a semiconductor device according to claim 1, wherein the first electrode is a top electrode of the capacitor and the second electrode is a bottom electrode of the capacitor.

3. The capacitor of a semiconductor device according to claim 1, wherein the first electrode is a bottom electrode of the capacitor and the second electrode is a top electrode of the capacitor.

4. The capacitor of the semiconductor device according to claim 3, further comprising:
an interlayer dielectric layer covering the second electrode; and
a via-pattern formed in the interlayer dielectric layer electrically connected to at least one of the base electrodes of the second electrode.

5. The capacitor of the semiconductor device according to claim 1, wherein the second electrode and the at least two pads are integrally formed with each other on a same layer.

6. The capacitor of the semiconductor device according to claim 1, wherein at least one of the bridge patterns is broken due to current applied through the at least two pads, such that at least one of the base electrodes of the plurality of base electrodes is electrically separated from the remaining base electrodes of the plurality of base electrodes.

7. The capacitor of the semiconductor device according to claim 1, wherein the second electrode further comprises:
an auxiliary electrode disposed between one of the plurality of base electrodes and one of the at least two pads, wherein the one of the at least two pads is connected to the second electrode through the auxiliary electrode; and
an additional bridge pattern connected between the auxiliary electrode and the one of the plurality of base electrodes, wherein another of the at least two pads is connected to the second electrode through the one of the plurality of base electrodes.

8. The capacitor of the semiconductor device according to claim 1, further comprising a connecting wire for connecting the second electrode to each of the at least two pads, wherein the connecting wire has a width larger than a width of the bridge patterns.

9. The capacitor of the semiconductor device according to claim 1, wherein the first electrode and the second electrode include at least one material selected from the group consisting of Ti, TiN, Ta, TaN, Cu, Al, Pt, Ru, Ir, Rh, Os and an alloy thereof.

10. The capacitor of the semiconductor device according to claim 1, wherein at least one of the base electrodes is electrically isolated from the remaining base electrodes.

11. The capacitor of the semiconductor device according to claim 1, wherein the bridge patterns have a design rule of about 0.3 μm to 0.001 μm.

12. The capacitor of the semiconductor device according to claim 1, wherein the bridge pattern has a predetermined width such that the bridge pattern disconnects upon an application of 0.5 A to 8 A of current through two of the at least two pads.

13. The capacitor of the semiconductor device according to claim 1, wherein the plurality of base electrodes of the second electrode comprises a main base electrode and at least one auxiliary electrode disposed at a periphery of the main base electrode,
wherein the bridge patterns connect the at least one auxiliary electrode to the main base electrode.

14. The capacitor of the semiconductor device according to claim 13, wherein each of the at least one auxiliary electrodes is connected to one of the at least two pads.

15. The capacitor of the semiconductor device according to claim 14, wherein at least one of the bridge patterns is broken due to current applied between a selected pad of the at least two pads and the main base electrode such that at least one of the auxiliary electrodes is electrically separated from the main base electrode.

16. A method for forming a capacitor of a semiconductor device, the method comprising:
forming a bottom electrode on a substrate;
forming a dielectric layer covering the bottom electrode;
forming a metal layer on the dielectric layer; and
patterning the metal layer to form a plurality of top electrodes overlapping the bottom electrode, bridge patterns for connecting adjacent top electrodes to each other, and pads connected to the top electrodes.

17. The method according to claim 16, wherein patterning the metal layer further comprises patterning the metal layer to form an auxiliary electrode connected between one of the top electrodes and one of the pads and an additional bridge pattern between the auxiliary electrode and the one of the top electrodes.

18. The method according to claim 16, further comprising applying current between two selected pads to disconnect the bridge pattern connected to the top electrode disposed between the selected pads such that the top electrode disposed between the selected pads is electrically isolated from remaining top electrodes of the plurality of top electrodes.

19. The method according to claim 16, further comprising:
forming an interlayer dielectric layer on an entire surface of the substrate after patterning the metal layer; and
forming a via-pattern in the interlayer dielectric layer such that the via-pattern is electrically connected to one of the top electrodes.

20. A method for forming a capacitor of a semiconductor device, the method comprising:
forming a first electrode on a substrate;
forming a dielectric layer covering the first electrode;
forming a metal layer on the dielectric layer; and
patterning the metal layer to form a second electrode overlapping the first electrode, at least one auxiliary electrode disposed at a periphery of the second electrode and overlapping the first electrode, a bridge pattern for connecting each auxiliary electrode of the at least one auxiliary electrode to the second electrode, and pads connected to auxiliary electrode.
